(19) United States
(12) Patent Application Publication
(10) Pub. No.: US 2026/0246431 A1
(43) Pub. Date: Aug. 20, 2026

(54) NON-LINEAR SELF-HEATING CORRECTION

(71) Applicant: MACOM Technology Solutions Holdings, Inc., Lowell, MA (US)

(72) Inventors: Anil Kumar, Lowell, MA (US); Vasilis Papanikolaou, Lowell, MA (US); Eric Iozsef, Lowell, MA (US)

(21) Appl. No.: 19/054,716

(22) Filed: Feb. 14, 2025

(51) Int. Cl. H03F 1/30; H03F 3/04; H03G 3/30

(52) U.S. Cl. CPC H03F 1/30; H03F 3/04; H03G 3/30; H03F 2200/447

(57) ABSTRACT

Circuits, semiconductor devices, and systems are provided. An illustrative system includes an amplifier circuit that produces non-linear self-heating errors during operation thereof. The system is further disclosed to include a replica amplifier circuit coupled with the amplifier circuit, where the replica amplifier circuit comprises a correction element that counteracts the non-linear self-heating errors produced in the amplifier circuit.

### FIELD OF THE DISCLOSURE

The present disclosure is generally directed toward circuits and, in particular, toward circuits used in high-speed broadband communications.

### BACKGROUND

High-speed broadband communication systems are constantly improving. As data rates increase, the requirements of components in the system are pushed to their physical limits. For example, active devices in cutting edge Bipolar CMOS (BiCMOS) and other CMOS processes delivering a broad range of gain (e.g., Ft/Fmax in range of 300G-400G, where Ft is transit frequency or unity current-gain frequency and where Fmax is a maximum oscillation frequency or unity power-gain frequency) are afflicted with self-heating error. The self-heating error, which may occur in lower frequency band can be difficult to correct. Drivers and/or receivers that rely on these types of bipolar devices suffer from significant eye-closure and thereby poor Bit Error Rate (BER), especially if self-heating errors are not corrected.

The self-heating error problem is further worsened in some circuits, such as a gilbert-cell type architecture, where the self-heating error is non-linear. Especially across a wide dynamic-range of gain the self-heating error may exhibit non-linear behaviors that may be either positive or negative. Correcting such self-heating errors are difficult, but important to help improve the overall performance of broadband communication drivers and/or receivers that operate across a broad range of gain.

### SUMMARY

Embodiments of the present disclosure contemplate solutions to the above-noted challenges. In particular, a circuit is proposed herein to effectively, efficiently, and accurately correct the non-linear self-heating errors described above. As a non-limiting example, a non-linear self-heating correction circuit is provided with a programmable correction element. The programmable correction element may be controlled by one or more Digital-to-Analog (DAC) control elements. The correction element may implement a non-linear correction transfer function that offsets the self-heating DAC control signal(s) in proportion to the gain of the main gain-stage

As will be described in further detail herein, self-heating error correction may utilize an offset-correction circuit where a negative fractional replica current of a main gain-stage is added to the output of the circuit. In some embodiments, the main gain-stage may be passed through a low-pass filter (LPF) as another mechanism to correct self-heating errors. In some designs, the replica circuit may utilize a fixed ratio of current of the main gain-stage with a linear degeneration. In such a situation, the self-heating filter bandwidth may be programmable to match the self-heating profile of the device.

Embodiments of the present disclosure further contemplate a replica amplifier circuit, which may also be referred to herein as a replica amplifier, that corrects for non-linear self-heating errors in an amplifier circuit to which the replica circuit is connected. For instance, an amplifier's gain control circuit may be offset relative to self-heating DAC outputs. Offsetting the self-heating DAC outputs enables the self-heating correction control to be delayed relative to the amplifier's gain control. The replica circuit, which receives the self-heating DAC outputs, can effectively react to the self-heating error in the amplifier circuit. Such an approach adds another dimension to the correction transfer function, which further accommodates cases where no correction is needed.

According to at least some embodiments of the present disclosure, a system is provided that includes: an amplifier circuit that produces non-linear self-heating errors during operation thereof; and a replica amplifier circuit coupled with the amplifier circuit, wherein the replica amplifier circuit comprises a correction element that counteracts the non-linear self-heating errors produced in the amplifier circuit.

In some embodiments, a semiconductor device is provided that includes: an amplifier circuit that produces non-linear self-heating errors during operation thereof; and a replica amplifier circuit coupled with the amplifier circuit, wherein the replica amplifier circuit comprises a correction element that counteracts the non-linear self-heating errors produced in the amplifier circuit.

In some embodiments, a circuit is provided that includes: an amplifier circuit that produces non-linear self-heating errors during operation thereof; and a replica amplifier circuit coupled with the amplifier circuit, wherein the replica amplifier circuit corrects the non-linear self-heating errors produced in the amplifier circuit.

According to at least some embodiments, the circuit, semiconductor device, and/or system may further include additional circuitry (e.g., one or more circuits) to support the operations of self-heating error correction. Such circuits may include components on a semiconductor device or package and/or components on an external processor. The circuit may include components solely on the semiconductor device or package or components solely on the external processor.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating components of a communication system according to at least some embodiments of the present disclosure;

FIG. 2 is a circuit diagram illustrating a first circuit according to at least some embodiments of the present disclosure;

FIG. 3 is a circuit diagram illustrating a second circuit according to at least some embodiments of the present disclosure;

FIG. 4 is a circuit diagram illustrating a third circuit according to at least some embodiments of the present disclosure;

FIG. 5 is a graph illustrating a device self-heating error as a function of frequency according to at least some embodiments of the present disclosure;

FIG. 6 is a graph illustrating the impact of self-heating error correction according to at least some embodiments of the present disclosure; and

FIG. 7 illustrates a method of operating a high-speed communication system according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing semiconductor designs.

While embodiments of the present disclosure will primarily be described in connection with circuits used in high-speed communication applications (e.g., high-bandwidth applications in which communications are exchanged at 10 MHz, 100 MHz, 1 GHz, or more or less), it should be appreciated that embodiments of the present disclosure are not so limited. Furthermore, while embodiments of the present disclosure are contemplated for use in connection with high-speed communications over copper or fiber, it should be appreciated that the claims are not limited to high speed electrical and optical or electro-optical (EO) communications. Further still, while embodiments of the present disclosure are particularly well-suited for use in communication systems that operate across a broad range of gain (e.g., between 0 dB and 10 dB of gain), it should be appreciated that embodiments of the present disclosure are suitable for use in communication systems that operate in different ranges of gain (e.g., narrower or broader ranges of gain).

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, across multiple packages, or combinations thereof.

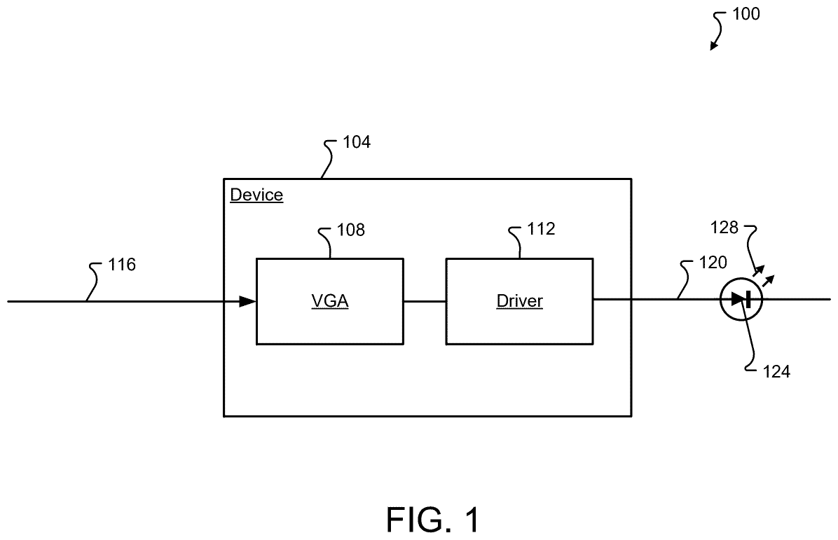

Referring initially to FIG. 1, components of an illustrative high-speed communication system 100 will be described in accordance with at least some embodiments of the present disclosure. The system 100 represents but one possible environment of use of the innovation(s) disclosed herein. More specifically, while system 100 is illustrated to include a transmission-side of a communication system, it should be appreciated that embodiments of the present disclosure may be utilized on a receiver side of a communication system without departing from the scope of the present disclosure. For instance, one or more of the circuit illustrated and described herein may be provided in a device comprising a driver for transmission of a communication signal and/or a device comprising a receiver of a communication signal.

As shown, the system 100 may include a device 104 configured to support high-speed or high-bandwidth communications. The device 104 may include components that facilitate the transmission or receipt of signals, which may correspond to optical signals or electrical signals. In the illustrated example, the device 104 is shown to include a variable gain amplifier (VGA) 108 connected with a driver 112. VGA 108 may receive an electrical signal as an input signal 116. The input signal 116 may be modulated or otherwise formatted to include data for transmission across a communication network or communication medium. The device 104 may be configured to support the exchange of data over the communication network or communication medium.

The VGA 108 may include one or more amplifier circuits that amplify the input signal 116 while maintaining the data of the input signal. The VGA 108 may output an amplified version of the input signal 116 to a driver 112, which utilizes the amplified version of the input signal 116 to produce an output signal 120. The output signal 120 may correspond to an appropriate input for an optoelectronic device, such as a diode 124. In some embodiments, the driver 112 may provide the diode 124 with an output signal 120 that comprises a substantially constant swing voltage (e.g., 1V peak-to-peak). The output signal 120 may still maintain data from the input signal 116, but in a format that is suitable for operating the diode 124. Non-limiting examples of a suitable diode 124 include a laser diode, a collection of laser diodes, a Light Emitting Diode (LED), a collection of LEDs, a VCSEL, an EML, a laser, an electrical load for electrical signaling, or the like.

In the illustrated embodiment, device 104 is configured to produce an optical communication signal 128 for transmission across an optical communication medium (e.g., an optical fiber). The optical communication signal 128 preserves the data of the output signal 120, which includes the data of the input signal 116.

It should be appreciated that embodiments of the present disclosure are not limited to devices 104 that exchange optical communication signals over an optical communication medium. For instance, the device 104 may alternatively or additionally include a driver 112 that provides an output to an electrical device, which produces an electrical signal for transmission across an electrical communication medium (e.g., a wire).

As can be appreciated, if the device 104 is receiving an optical signal from an optical communication medium rather than transmitting the optical signal, the diode 124 may be configured to receive the optical signal and convert the optical signal into an electrical signal that is exchanged with other components of the device 104 supporting high-speed communications in an electrical domain. More specifically, the optical signal may be received from an end of a fiber optic cable at a photodiode, which converts the optical signal into an electrical signal.

Whether operating as a transmitter or receiver, the device 104 may be configured to support high-speed data exchanges over a communication medium or network. As a non-limiting example, the device 104 may be configured to support broadband wireline communications. Such communication exchanges may occur at relatively high frequencies across a large range of gain. As a non-limiting example, communications may be exchanged at frequencies, such as 10 MHz, 100 MHz, 1 GHz, or more or less.

Components of the device 104 may be provided in one or more semiconductor packages. Alternatively or additionally, components of device 104 may be provided as one or more separate circuit elements on a PCB. The device 104 may include a housing that contains or protects all of the components of system 100 even though the diode 124 is shown as being separate from device 104. In other words, the system 100 may include a single housing that contains the components of the device 104 along with the diode 124 to protect such components from environmental hazards.

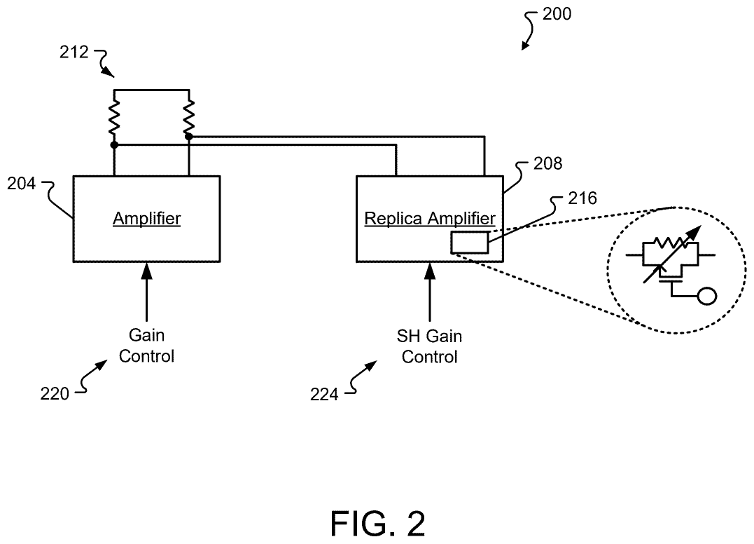

With further reference to FIGS. 2-4, various examples of circuits 200, 300, 400 that may be provided in a device 104 or system 100 will be described in accordance with at least some embodiments of the present disclosure. The circuits 200, 300, 400 depicted and described herein correspond to examples of possible circuits that may be used to provide self-heating error correction, where such self-heating errors are linear or non-linear in nature.

Referring now to FIG. 2, a first circuit 200 is illustrated to include an amplifier circuit 204 and a replica amplifier circuit 208. One or both circuits 204, 208 may be included in a VGA 108 and/or driver 112 without departing from the scope of the present disclosure. The amplifier circuit 204 may be coupled with the replica amplifier circuit 208 via one or more resistors 212. Output(s) of the amplifier circuit 204 may be provided as corresponding input(s) to the replica amplifier circuit 208. For example, a first output signal (e.g., outn) of the amplifier circuit 204 may be provided as a first input to the replica amplifier circuit 208. Similarly, a second output signal (e.g., outp) of the amplifier circuit 204 may be provided as a second input to the replica amplifier circuit 208.

The amplifier circuit 204 may be controlled by a gain control signal 220, which may also be referred to herein as an amplifier gain control signal. The gain control signal 220 may be operated according to control logic in a separate control element of the device 104.

The replica amplifier circuit 208 may be controlled by a self-heating (SH) gain control signal 224. The SH gain control signal 224, which may also be referred to herein as a self-heating DAC output or SH DAC, may be generated based on the gain control signal 220. In other words, the gain control signal 220 may be processed by control logic in the device 104 to produce the SH gain control signal 224. As an example, the SH gain control signal 224 may be offset relative to the gain control signal 220, thereby allowing for an appropriate delay in operation of the replica amplifier circuit 208 relative to the amplifier circuit 204. In other words, the SH gain control signal 224 may be generated in response to changes made to the gain control signal 220 and such changes to the SH gain control signal 224 may be offset in the gain-domain relative to changes made in the gain control signal 220. A generic self-heating gain-control function can be envisaged as sum of multiple function for different gain-range of the main gain-stage as described by equation:

$${Gsh}_{[ Gctl = 0 - > N ]} = {f}_{1} ( {Gm}_{[ Gctl = 0 - > A ]} ) + {f}_{2} ( {Gm}_{[ Gctl = A - > B ]} ) + … . {f}_{n} ( {Gm}_{[ Gctl = ( N - 1 ) - > N ]} ) ,$$

where f1, f2, fn can be linear or non-linear, including but not limited to square law, quadratic, exponential; Gsh is the self-heating gain; Gm is the main path gain, Gctl is the gain setting control value, where A, B, N are incrementally increasing gain control code.

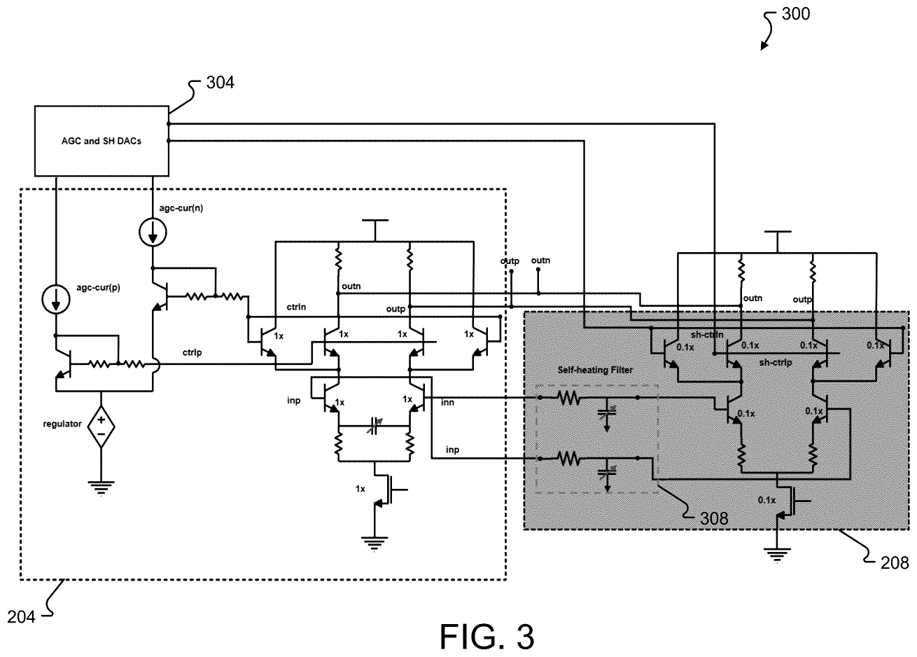

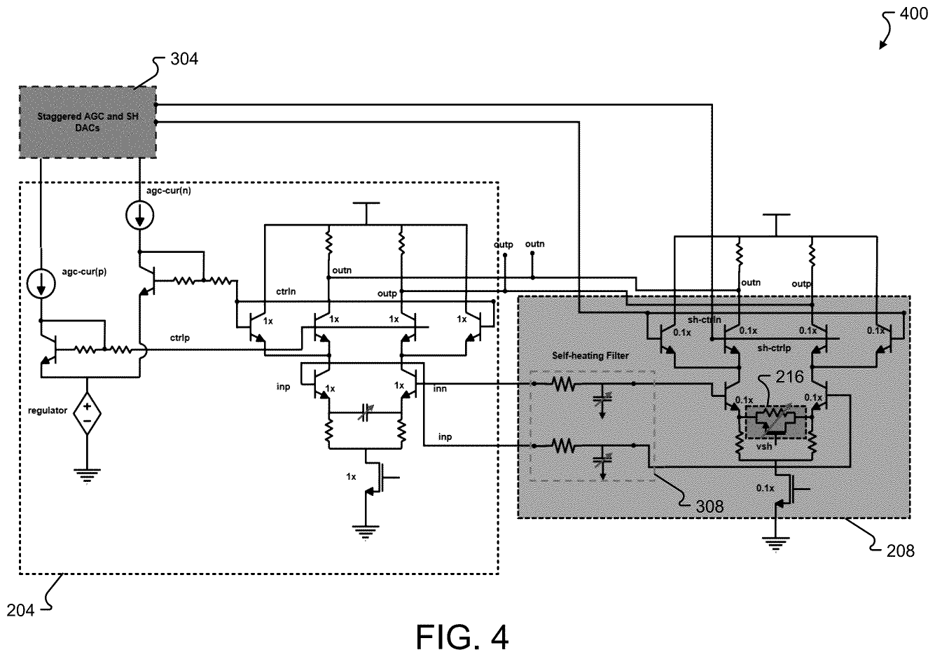

The SH gain control signal 224 may be adjusted in a non-linear fashion to accommodate for non-linear changes in self-heating error in the amplifier 204. As will be depicted and described in further detail herein with respect to FIGS. 3 and 4. The replica amplifier circuit 208 may include a number of circuit components that mirror or replicate components in the amplifier circuit. The components of the replica amplifier circuit 208 are designed to replicate but counteract self-heating errors created within the amplifier circuit 204. In some embodiments, the replica amplifier circuit 208 may include one or more correction elements 216 that are configured to control the operations of the replica amplifier circuit 208. More specifically, the correction element(s) 216 may include one or more components that are programmable and capable of correcting self-heating errors in the amplifier circuit 204. In some embodiments, the correction element(s) 216 may include a network of control elements, which are configurable to operate in a non-linear fashion.

In some embodiments, the correction element(s) 216 may include a combination of one or more resistors and one or more transistors. The one or more transistors may receive the SH gain control signal 224 and, based on the value of the SH gain control signal 224, turn on or off. Depending upon whether the one or more transistors are in an on state or an off state, the corresponding resistor may be effectively added to other circuitry in the replica amplifier circuit 208. For instance, the correction element(s) 216 may include a first controllable resistor and a second controllable resistor. The first controllable resistor may be activated (e.g., effectively incorporated into the replica amplifier circuit) when a first corresponding transistor is activated by the SH gain control signal 224. The second controllable resistor may be activated at a different time from the first controllable resistor (e.g., when a second corresponding transistor is activated by the SH gain control signal 224). Thus, as can be appreciated, the SH gain control signal 224 may include multiple sub-signals that operate different components within the correction element(s) 216. It should also be appreciated that the correction element(s) 216 can include a network of circuit elements (e.g., a plurality of cascaded resistor/transistor pairs) that operate in synchronization with one another and responsive to the SH gain control signal 224.

In some embodiments, the correction element(s) 216 may include a plurality of resistor/transistor pairs that are activated/deactivated at different times to correct non-linear of the amplifier circuit 204 at different gain levels (e.g., when different gain control signals 220 are applied to the amplifier 204). More specifically, and without limitation, the correction element(s) 216 may enable the replica amplifier circuit 208 to operate according to a non-linear correction transfer function. The correction element(s) 216 may be operated with the SH gain control signal 224, which is offset from the main gain control signal 220, further improving the responsiveness of the replica amplifier circuit 208 to self-heating error correction for the amplifier circuit 204.

The resistance of the resistors 212 may be referred to as RL whereas the resistance provided by the correction element(s) 216 may be referred to as Re. The overall gain of the SH replica circuit 208 may correspond to a ratio of RL to Re or RL divided by Re. As noted above, adjustments to the resistance Re may be made to correct self-heating errors in the amplifier 204. In some embodiments, this may be accomplished by providing a plurality of resistor/transistor pairs that are operated synchronously. An alternative approach would be to provide a non-linear control voltage to the transistor (e.g., the MOSFET) of the correction element(s) 216. By providing a non-linear control voltage to the transistor of the correction element(s) 216, the resistance Re may be adjusted in a non-linear fashion to accommodate or mimic non-linear changes in self-heating errors of the amplifier circuit 204.

Referring now to FIG. 3, a first example of a circuit 300 that is used as part of circuit 200 or to entirely implement circuit 200 will be described. The circuit 300 is shown to include control elements 304 (e.g., a controller, a control circuit, a logic circuit, or the like) that provide the gain control signal 204 to an amplifier circuit 204 as well as SH gain control signal 224 to the replica amplifier circuit 208. In some embodiments, the control elements 304 may include one or a plurality of controllers, control circuits, logic circuits, Application Specific Integrated Circuits (ASICs), microcontrollers, Programmable Logic Circuits (PLCs), combinations thereof, or the like. As noted above, the control elements 304 may provide linear or non-linear SH gain control signal(s) 224 to the replica amplifier circuit 208 based on the gain control signal 220 provided to the amplifier circuit 204 and/or based on changes in self-heating errors observed within the amplifier circuit 204.

FIG. 3 further illustrates a self-heating filter 308, which may also be used within the replica amplifier circuit 208 to correct self-heating errors within the amplifier circuit 204. Self-heating correction provided by the replica amplifier circuit 208 may be considered an offset-correction circuit where a negative fractional replica of main gain-stage is added to the output of the overall circuit 300. In the configuration of FIG. 3, the circuit 300 provides a replica amplifier circuit 208 without the correction element(s) 216. Rather, the replica amplifier circuit 208 in circuit 300 provides a fixed ratio of the main gain stage with a linear degeneration. Here, the self-heating filter 308 bandwidth may be programmable.

FIG. 4 illustrates another possible circuit 400 that may be used as part of circuit 200 or to entirely implement circuit 200 in accordance with at least some embodiments of the present disclosure. The circuit 400 is shown to include many of the elements included in circuit 300. Circuit 400 is further shown to include correction element(s) 216 that help the replica amplifier circuit 208 correct self-heating errors in the amplifier circuit 204. In the example of FIG. 4, the correction element(s) 216 correspond to at least one resistor that is adjustable under control of a transistor. The transistor of the correction element(s) 216 may be controlled with a self-heating voltage vsh, which may correspond to an instance of the SH gain control signal 224. In other words, the self-heating voltage vsh provided to the correction element(s) 216 may be produced by the control element 304. As self-heating in the amplifier 204 may be non-linear in nature, the correction element(s) 216 may be controlled in a non-linear fashion to mimic and correct the non-linear self-heating error.

While the correction element(s) 216 are depicted as being placed at an output of a transistor network in the replica amplifier circuit 208, it should be appreciated that the correction element(s) 216 may be placed at other locations within the replica amplifier circuit 208 without departing from the scope of the present disclosure. The particular placement of the correction element(s) 216 is useful given the configuration of the transistor network and the resistors placed between the transistor network and ground. Such a placement help to adjust the overall resistance of the transistor network, which is mimicking or following a corresponding transistor network in the amplifier circuit 204. As shown in FIG. 4, the transistors in transistor network of the replica amplifier circuit 208 are shown to be a fraction of the size (e.g., 0.1) of transistors in the transistor network of the main amplifier circuit 204

As can be appreciated, devices 104 designed for a large input-range may be desired to maintain a large dynamic-range of gain to deliver a given output amplitude irrespective of input-amplitude. A gilbert-cell type architectures used in VGAs of such devices are afflicted with both positive and negative self-heating error across the wide gain range, one such example is ~0-20 dB. Such devices may be particularly benefited from the use of a replica amplifier circuit 208 as depicted and described herein. It should be appreciated that other devices (e.g., non-biploar devices and/or non-gilbert-cell type architectures) may also benefit from the use of a replica amplifier circuit 208 as depicted and described herein.

Self-heating gain variations up to +/−3 dB have been observed in some devices 104 depending on the over-all device gain. At this level of self-heating offset, the output-eye is severely impaired due to vertical-eye closure thereby increasing BER. In such designs, the conventional self-heating correction provided by a circuit, such as circuit 300, which provides fixed degeneration may not provide a desired correction across the entire gain range. A circuit, such as circuit 400, however, may implement the non-linear self-heating correction that is desirable for solutions employing a MOS-based non-linear resistor. The ability to offset the gain control signal 220 relative to the SH gain control signal 224 (e.g., to accommodate the onset of self-heating replica) provides another layer of control for non-linear error correction. Such solutions can be configured to correct the self-heating error across a wide gain range with the residual error of approximately 0.5 dB or better.

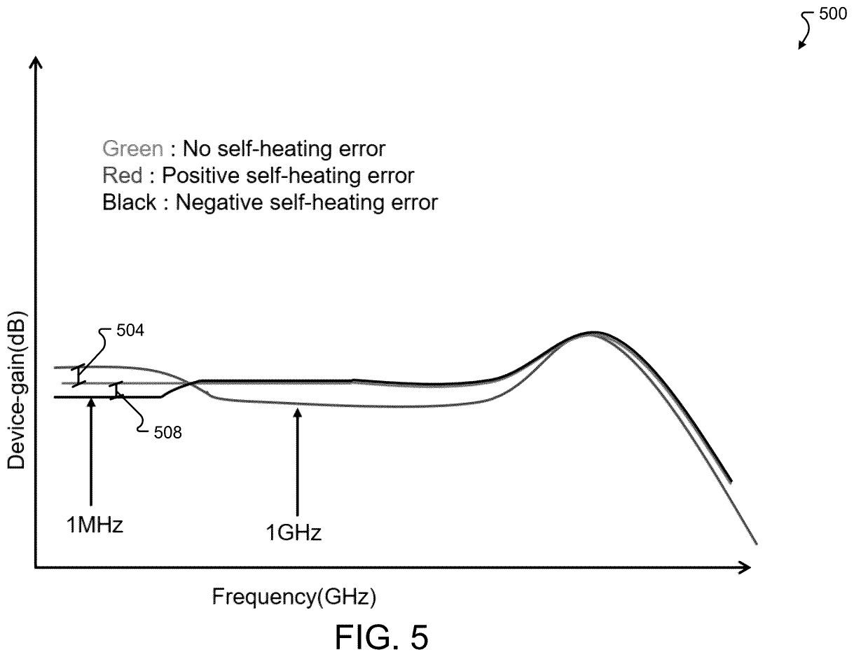

For example, as can be seen in FIG. 5, device gain as a function of frequency 500 illustrates that self-heating errors 504, 508 may be negative or positive in nature. A positive self-heating error 504 may occur in some instances whereas a negative self-heating error 508 may occur in other instances and such errors 504, 508 may occur at lower operating frequencies of the device 104. For instance, the self-heating errors 504, 508 are shown to occur at approximately 50 MHz. Self-heating errors may also occur at higher or lower frequencies. As described herein, self-heating errors may refer to a difference in gain of the device 104 or the circuit therein (e.g., the amplifier circuit 204) at 1 MHz and 1 GHz. In the illustrated example, the self-heating error may correspond to the device gain at 1 MHz minus the device gain at 1 GHz.

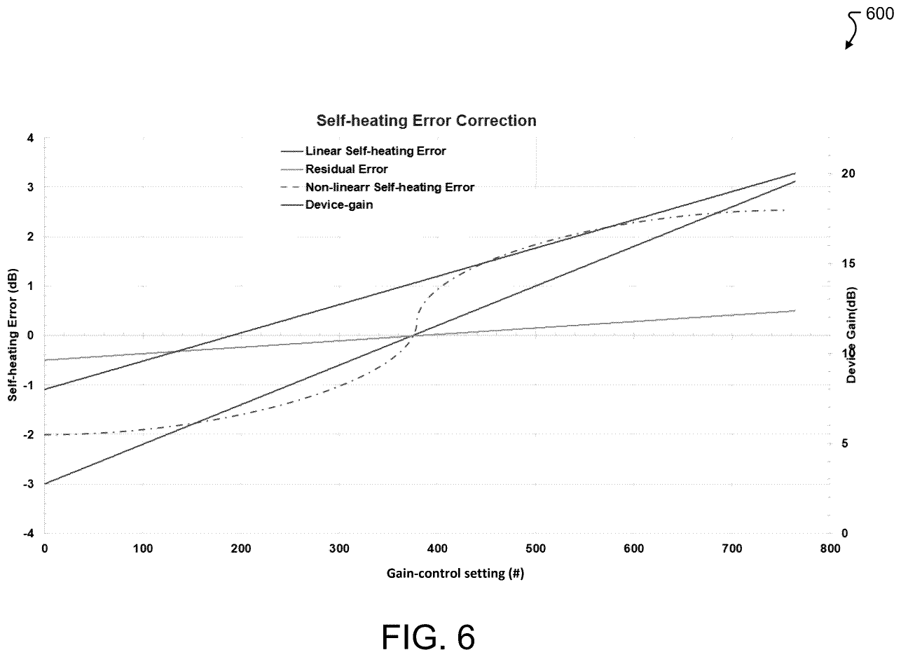

FIG. 6 illustrates a self-heating error correction diagram 600, which helps visualize the impact of self-heating error correction in the device 104. As shown in the diagram 600, the self-heating error is reduced from +/−3 dB to +/−0.5 dB by implementing a replica amplifier circuit 208 with correction element(s) 216 as depicted and described herein. It can also be seen that substantially any non-linear function can be implemented by careful design of the correction element(s) 216 or the control thereof to address the non-linear nature of self-heating error.

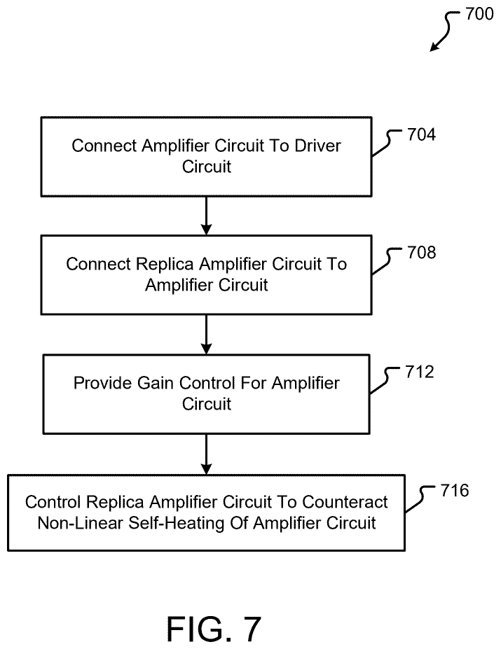

Referring now to FIG. 7, a method 700 will be described in accordance with at least some embodiments of the present disclosure. The method 700 begins by connecting an amplifier circuit, such as a VGA 108, to a driver circuit, such as driver 112 (step 704).

The method 700 continues by connecting a replica amplifier circuit to the amplifier circuit (step 708). In some embodiments, the replica amplifier circuit may correspond to a replica amplifier circuit 208 with correction element(s) 216 and the amplifier circuit may correspond to an amplifier circuit 204 within a larger amplifier circuit 200.

The method 700 continues by providing a gain control signal 220 to the amplifier circuit (step 712). Simultaneous with step 712 or in response to step 712, the method 700 may further include controlling a replica amplifier circuit to counteract or correct self-heating errors in the amplifier circuit (step 716). For instance, SH gain control signal 224 may be provided to the replica amplifier circuit 208 to adjust the correction element(s) 216 in a non-linear fashion, thereby allowing the replica amplifier circuit 208 to correct non-linear self-heating errors in the amplifier circuit 204.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A system, comprising:
an amplifier circuit that produces non-linear self-heating errors during operation thereof; and
a replica amplifier circuit coupled with the amplifier circuit, wherein the replica amplifier circuit comprises a correction element that counteracts the non-linear self-heating errors produced in the amplifier circuit.

2. The system of claim 1, wherein the correction element comprises at least one resistor controlled by at least one transistor.

3. The system of claim 2, wherein the correction element comprises a plurality of resistor and transistor pairs that operate responsive to a self-heating gain control signal.

4. The system of claim 3, wherein each resistor and transistor pair in the plurality of resistor and transistor pairs activates and/or deactivates at a different gain setting.

5. The system of claim 2, wherein the at least one transistor is controlled by a non-linear control voltage.

6. The system of claim 1, further comprising:
a control element that provides the amplifier circuit with a gain control signal and the replica amplifier circuit with a self-heating gain control signal.

7. The system of claim 6, wherein the self-heating gain control signal is offset relative to the gain control signal.

8. The system of claim 6, wherein the self-heating gain control signal is produced in response to the gain control signal.

9. The system of claim 1, wherein the amplifier circuit and the replica amplifier circuit are provided as part of a variable gain amplifier (VGA).

10. The system of claim 9, further comprising a driver coupled with the VGA, wherein the driver receives an output of the VGA.

11. The system of claim 9, further comprising a diode coupled with the driver, wherein the driver operates the diode to produce an optical communication signal according to the output of the VGA.

12. A semiconductor device, comprising:
an amplifier circuit that produces non-linear self-heating errors during operation thereof; and
a replica amplifier circuit coupled with the amplifier circuit, wherein the replica amplifier circuit comprises a correction element that counteracts the non-linear self-heating errors produced in the amplifier circuit.

13. The semiconductor device of claim 12, wherein the amplifier circuit comprises at least one bipolar transistor.

14. The semiconductor device of claim 12, wherein the amplifier is provided as part of a gilbert-type architecture.

15. The semiconductor device of claim 12, wherein the correction element comprises at least one resistor controlled by at least one transistor.

16. The semiconductor device of claim 15, wherein the correction element comprises a plurality of resistor and transistor pairs that operate responsive to a self-heating gain control signal.

17. The semiconductor device of claim 16, wherein each resistor and transistor pair in the plurality of resistor and transistor pairs activates and/or deactivates at a different time.

18. The semiconductor device of claim 15, wherein the at least one transistor is controlled by a non-linear control voltage.

19. A circuit, comprising:
an amplifier circuit that produces non-linear self-heating errors during operation thereof; and
a replica amplifier circuit coupled with the amplifier circuit, wherein the replica amplifier circuit corrects the non-linear self-heating errors produced in the amplifier circuit.

20. The circuit of claim 18, wherein the replica amplifier circuit comprises a correction element that corrects the non-linear self-heating errors produced in the amplifier circuit.

21. The circuit of claim 19, wherein the amplifier circuit comprises a first transistor network, wherein the replica amplifier circuit comprises a second transistor network that mirrors the first transistor network, and wherein the correction element comprises a controllable circuit element coupled to the second transistor network.
